(19) United States
(12) Patent Application Publication
(10) Pub. No.: US 2017/0033534 A1
(43) Pub. Date: Feb. 2, 2017

(54) VCSEL STRUCTURE

(71) Applicant: Danmarks Tekniske Universitet, Kgs. Lyngby (DK)

(72) Inventors: Il-Sug CHUNG, Kgs. Lyngby (DK); ALIREZA Taghizadeh, Virum (DK)

(21) Appl. No.: 15/302,346

(22) PCT Filed: Apr. 7, 2015
(86) PCT No.: PCT/EP2015/057522

§ 371 Date: Oct. 6, 2016

(30) Foreign Application Priority Data
Apr. 7, 2014 (EP) 14163768.6

(51) Int. Cl. H01S 5/183; H01S 5/026

(52) U.S. Cl. CPC H01S 5/18319; H01S 5/18386; H01S 5/026

(57) ABSTRACT

The invention relates to a VCSEL structure based on a novel grating reflector. The grating reflector (1) comprises a grating layer (20) with a contiguous core grating region having a grating structure, wherein an index of refraction of high-index sections (21) of the grating structure is at least 2.5, and wherein an index of refraction of low-index sections (22) of the grating structure is less than 2. The core grating region defines a projection in a direction normal to the grating layer. The grating reflector further comprises a cap layer (30) abutting the grating layer (20), and an index of refraction of the cap layer within the projection of the core grating region onto the cap layer is at least 2.5, and within the projection of the core grating region, the cap layer is abutted by a first solid dielectric low-index layer, an index of refraction of the first low-index layer or air being less than 2; and within the projection of the core grating region, the grating layer is also abutted by a second low-index layer and/or by air, an index of refraction of the second low-index layer or air being less than 2. The VCSEL structure furthermore comprises a first reflector and an active region for providing a cavity and amplification. The cap layer (30) may comprise an active layer (32) between cladding layers (31,33) and electrical contacts (35,36) to provide a current through the active layer. Current confinement may be realized by low-index oxide regions (60).

### TECHNICAL FIELD

This invention relates to a grating reflector and VCSEL structures employing embodiments of the grating reflector.

### BACKGROUND OF THE INVENTION

Sub-wavelength high-index-contrast gratings (HCGs) have received lots of attention due to special properties such as broadband high reflection spectrum and ultra-high Q resonance effect. As a reflector, it can be approximately 50 times thinner than a conventional distributed Bragg reflector (DBR), but still offer high reflectivity over a much significantly broader spectral width, properties that make it useful in a wide application range, including lasers, photodetectors, filters, splitters, couplers, etc. They have been implemented in vertical cavity surface emitting lasers (VCSELs) and resonant-cavity-enhanced photodetectors (RCEPDs) in place of conventional DBRs. In addition several unique characteristics of HCGs in VCSEL structures, such as a strong single-transverse-mode operation, broad wavelength tunability, and light emission into an in-plane silicon photonics chip have been shown.

Using HCG as a high Q resonator, a very compact (small modal volume) with ultra-high quality factor lasing device has been demonstrated. Fully rigorous electromagnetic solutions known as RCWA exist for gratings, although they require heavy mathematical formalism. Different groups investigated the physics behind HCGs' properties. In all the literature on the HCG mirrors, the grating is surrounded by low index materials. Even if the device substrate is a high-index material, a layer with low-index material is said to be required to obtain the HCG properties.

U.S. Pat. No. 7,304,781 B2 is an example of patent prior art describing HCG mirrors. Again, the high-index regions are surrounded by material having a relatively low refractive index.

International patent application publication WO 2013/110004A1 discloses a “0-gap” HCG. The 0-gap HCG is defined by only three geometrical parameters, i.e., grating period, grating thickness, and grating duty cycle. The incident medium is high refractive index material 114. This 0-gap HCG does not provide a reflectivity higher than 99.5% according to FIG. 8, and the bandwidth over which the reflectivity is sufficiently high is relatively narrow due to the inherent properties of 0-gap HCGs.

The structures in WO 2013/110004A1 therefore have some undesirable properties.

The present invention addresses some of these undesirable properties and provides an alternative VCSEL structure that allows for more design flexibility.

### SUMMARY OF THE INVENTION

Despite the fact that in the literature HCGs consist of a grating sections having high-index material surrounded by a low-index material, the inventors of the present invention have realized that similar properties can be obtained even with a high-index material, a “cap layer”, abutting the grating structure. The resulting structure will be referred to as a grating reflector. Even with a relatively thick layer (several times the grating's thickness) of high-index material, this structure can have special and advantageous properties. The working mechanism of the grating reflector can be more complex and, more importantly, more flexible than the conventional HCG mirror. For practical purposes, the cap layer is somewhere between 300 nm to 1 micron at 1.5 micron wavelength, but it can also be thinner or thicker.

The addition of the cap layer provides several advantages over conventional HCGs. It can improve some of the reflection properties, e.g. broaden the bandwidth. From a fabrication standpoint, especially for devices with active material, it can ease the fabrication process due to the possibility of integrating active material inside the grating reflector. Furthermore, the invention can improve device performance, such as tuning rate, due to a smaller effective cavity length in RCEPDs.

Most of the materials that can be used in the present invention have chromatic dispersion, which is the phenomenon that the phase velocity of light travelling in the material varies with the wavelength of the light. In the present specification, particularly in the claims, “refractive index” or “index of refraction” of a material refers, unless otherwise specified, to generally accepted values of the refractive index for that material at a free-space wavelength of 1.5 um. Table 1 shows values for common high-index materials applicable in the context of the present invention. At high frequencies, the refractive indices for those materials change rapidly with decreasing wavelength, typically increasing at first, and then decreasing to values lower than 2.5. Table 1 also shows the refractive indices at a free-space wavelength of 250 nm to illustrate this.

This definition of refractive index used herein shall not be construed as limiting the scope of the invention. The definition is used because a number of materials that are advantageous in embodiments of aspects of the present invention have refractive indices within certain intervals at various wavelengths. Using the refractive index at a certain wavelength as a reference, the concept of refractive index or index of refraction as these entities pertain to the claims invention becomes unambiguous.

TABLE 1
Index of refraction for high-index materials

| Material | n (at 1.5 um) | n (at 0.25 um) |
|---|---|---|
| Si | 3.48206 [1] | 1.5808 [2] |
| InP | 3.17085 [1] | 2.297 [2] |
| GaAs | 3.39886 [1] | 2.5198 [2] |

TABLE 2
Index of refraction for low-index materials

| Material | n (at 1.5 um) | n (at 0.25 um) |
|---|---|---|
| Si3N4 | 1.99038 [3] | 2.28189 [4] |
| SiO2 | 1.52837 [5] | 1.60035 [5] |
| Al2O3 | 1.74687 [6] | 1.8337 [6] |
| Air | 1.0002733 [7] | 1.00030148 [7] |

### REFERENCES

[1] Handbook of Optics, 3rd edition, Vol. 4. McGraw-Hill 2009

[2] D. E. Aspnes and A. A. Studna. Dielectric functions and optical parameters of Si, Ge, GaP, GaAs, GaSb, InP, InAs, and InSb from 1.5 to 6.0 eV, Phys. Rev. B 27, 985-1009 (1983)

[3] http://www.filmetrics.com/refractive-index-database/Si3N4/Silicon-Nitride-SiN

[4] T. Bååk. Silicon oxynitride; a material for GRIN optics, Appl. Optics 21, 1069-1072 (1982)

[5] Gorachand Ghosh. Dispersion-equation coefficients for the refractive index and birefringence of calcite and quartz crystals, Opt. Commun. 163, 95-102 (1999)

[6] SOPRA N&K Database

[7] Philip E. Ciddor. Refractive index of air: new equations for the visible and near infrared, Appl. Optics 35, 1566-1573 (1996)

A first aspect of the invention provides a new type of VCSEL. This VCSEL comprises:

A first aspect of the invention provides a new type of a grating reflector. The grating reflector comprises:
a first reflector,
a grating reflector, the grating reflector forming an optical cavity with the first reflector, and
a first active region located in the cap layer of the grating reflector for generating or absorbing photons.

The cap layer is a crucial part of the grating reflector. Generally, the grating reflector comprises:
a grating layer having a first side and having a second side opposite the first side and comprising a contiguous core grating region having a grating structure, wherein an index of refraction of high-index sections of the grating structure is at least 2.5, and wherein an index of refraction of low-index sections of the grating structure is less than 2, the core grating region defining a projection in a direction normal to the grating layer,
a cap layer having a first side and having a second side opposite the first side, the first side of the cap layer abutting the second side of the grating layer, and an index of refraction of the cap layer within the projection of the core grating region onto the cap layer is at least 2.5,
and
within the projection of the core grating region, the second side of the cap layer is abutted by a first solid dielectric low-index layer, an index of refraction of the first low-index layer being less than 2, and
within the projection of the core grating region, the first side of the grating layer is abutted by a second dielectric low-index layer and/or by air, an index of refraction of the second low-index layer or air being less than 2.

A “side” of a layer refers to an in-plane oriented face of the layer that meets another in-plane oriented face of another layer, or meets a grating, or air. From the figures, it is clear that in a “grating layer” as referred to in the present invention, high-index sections and low-index sections alternate in an in-plane direction.

Compared to e.g. WO 2013/110004 A1, the first reflector and grating reflector form an optical cavity that can be significantly shorter than the cavity 60 in D1.

To obtain a stronger effect of the grating, it can be advantageous that the grating layer within the core grating region comprises at least 3 high-index sections.

The high-index regions of the grating region can be made of for instance Si or be InP-based or GaAs-based.

The second low-index layer may comprise or consist of for instance SiNx, SiO₂, or AlOx, or an equivalent material fulfilling the conditions for a second low-index layer.

The cap layer comprises a first active region and may comprise at least two contacts positioned to allow a voltage to be applied across the first active region for either generating photons or changing an absorption of the first active region.

The cap layer may comprise a first cladding layer and a second cladding layer, with the first active region interposed therebetween.

In certain preferred embodiments, a thickness of the cap layer is at most 3 microns, such as at most 1.5 microns, such as at most 0.6 microns. Preferably, the thickness of the cap layer is in the interval 300 nm to 1.5 microns.

In some embodiments, the VCSEL structure further comprises a second active region arranged so the first low-index layer is situated between the first active region and the second active region.

In some embodiments, the first reflector is a distributed Bragg reflector. Alternatively, it is a grating reflector designed to have a high reflectivity, such as at least 99%, such as at least 99.5%, such as at least 99.8%, or even higher. Alternatively, it may be a high-contrast grating (HCG), a metallic reflector, or any other reflector having the abovementioned high reflectivity.

By adding at least two second active region contacts, application of a forward-bias voltage or reverse-bias voltage across the second active region is enabled. Then an optical output from the optical cavity can be modulated when a sufficient and time-varying reverse or forward bias voltage is applied across the second active region. Preferably, the first active region contacts are located on one side of the first low-index layer, and the second active region contacts are located on a side of the first low-index layer opposite the side of the first active region contacts. The contacts are typically not in direct contact with the first low-index layer, which the drawings will clearly show. The first low-index layer is typically non-conducting or at least has a high resistance, whereby the application of a voltage across the first active region is not affected by application of a voltage across the second active region.

In some embodiments, the VCSEL structure includes an output waveguide in the grating layer, the output waveguide comprising an external waveguide beginning from and extending beyond a projection of a first edge of the optical cavity onto the grating layer. This output waveguide enables coupling light from the optical cavity out in a lateral direction rather than in a vertical direction (such as through the first reflector). Preferably, this is combined with a first reflector and grating reflector having a combined normal-incidence reflectivities of at least 99.8%. Preferably, the normal-incidence reflectivity of the first reflector exceeds the normal-incidence reflectivity of the grating reflector. The result is that most of the optical power is coupled out via the output waveguide rather than in a direction normal to the first reflector.

Preferably, the external waveguide is at least 10 microns long.

In some embodiments, the VCSEL structure comprises a core section in which a normal-incidence reflectivity of the combined cap layer and grating layer is at least 99%, such as at least 99.8%.

In some embodiments, the core section extends to the beginning of the external waveguide.

In some embodiments, the VCSEL structure comprises a core section with grating parameters that result in a normal-incidence reflectivity of the combined cap layer and grating layer of at least 99%, such as at least 99.8%. The VCSEL structure furthermore comprises a coupling section between the core section and the external waveguide, and the coupling section has grating parameters that are different from the grating parameters of the core section.

In some embodiments, the grating layer in the coupling section comprises a narrow low-index section that has a width in the interval 35 to 65% of a smallest width of low-index sections within the core section, and the narrow low-index section abuts the external waveguide. In some embodiments, the grating layer within the coupling section consists of only the narrow low-index layer.

In some embodiments, the external waveguide is integral with a wide high-index section in the coupling section, the wide high-index region having a width exceeding a highest width of high-index sections within the core section.

In some embodiments, the VCSEL structure furthermore comprises a confinement section having grating parameters different from grating parameters of the core section. In some embodiments, a vertical resonance wavelength in the confinement section differs from a vertical resonance wavelength in the core section. Then there is no mode in the confinement section matching the vertical resonance wavelength mode in the core section, and thus light from the core section cannot propagate into the confinement section.

In some embodiments, the grating layer in the confinement section is a Bragg reflector or equivalent structure having a stop band around a vertical cavity resonance wavelength of the core section. In some embodiments, it comprises alternately high-index and low-index sections each of which has an optical width of one quarter of the vertical resonance wavelength of the core section. Generally, the widths may also fall within +/−25% of the one quarter of the vertical resonance wavelength of the core section.

In some embodiments, the external waveguide tapers from a first width at the beginning of the external waveguide, to a narrower width.

In some embodiments, a normal-incidence reflectivity of the first reflector equals or exceeds a normal-incidence reflectivity of the combined cap layer and grating layer in the core section. This ensures a higher coupling of optical power from the optical cavity into the external waveguide.

In some embodiments, the VCSEL structure comprises:
at least two first active region contacts positioned to allow a voltage to be applied across the first active region for either generating photons or changing an absorption of the first active region,
wherein a shortest distance between the at least two first active region contacts is at least 80% of a width of the external waveguide at the beginning of the external waveguide.

In some embodiments, the first active region contacts are located in a north position and a south position relative to the core section and the external waveguide is located in an east position relative to the core section, when seen in a direction normal to the first reflector.

### BRIEF DESCRIPTIONS OF THE DRAWINGS

FIGS. 1A, 1B, 1C and 1D are cross-sectional views of embodiments of a grating reflector in accordance with an aspect of the present invention.

FIGS. 2A and 2B are top views of exemplary one-dimensional grating structures for a grating reflector.

FIG. 2C is the top view of an example of a two-dimensional grating structure for a grating reflector.

FIG. 2D is the top view of an example of a circular grating structure for a grating reflector.

FIG. 3A is an example of a reflection spectrum for a prior art high-index-contrast grating.

FIG. 3B is an example of a reflection spectrum of a grating reflector in accordance with an aspect of the present invention.

FIG. 4A is a schematic illustration of a VCSEL structure with a grating reflector that can be operable as a reflectoer or as an intergrated intensity modulator.

FIG. 4B is an embodiment of a VCSEL that employs the VCSEL structure from FIG. 4A. The grating reflector is operable as an integrated intensity modulator.

FIG. 5A is a schematic illustration of a VCSEL with a hybrid grating reflector generating light or a resonant-cavity-enhanced photodetector (RCEPD) with a hybrid grating reflector absorbing light.

FIG. 5B is an embodiment of the VCSEL or RCEPD structure illustrated in FIG. 5A.

FIG. 5C is an embodiment of the VCSEL or RCEPD structure illustrated in FIG. 5A.

FIG. 6A: An embodiment of a VCSEL structure emitting light into an in-plane waveguide.

FIG. 6B: Top view of a VCSEL structure in accordance with an embodiment of the invention.

FIG. 6C: An embodiment of a VCSEL structure emitting light into an in-plane waveguide.

FIG. 6D: An embodiment of a VCSEL structure emitting light into an in-plane waveguide.

FIG. 6E: An embodiment of a VCSEL structure emitting light into an in-plane waveguide.

FIG. 6F: An embodiment of a VCSEL structure emitting light into an in-plane waveguide.

### DETAILED DESCRIPTION OF SELECTED EMBODIMENTS

The invention will now be exemplified with reference to the accompanying drawings. Reference signs in this specification, including in the claims, are not to be construed as limiting the scope of the invention. The drawings are not necessarily drawn to scale.

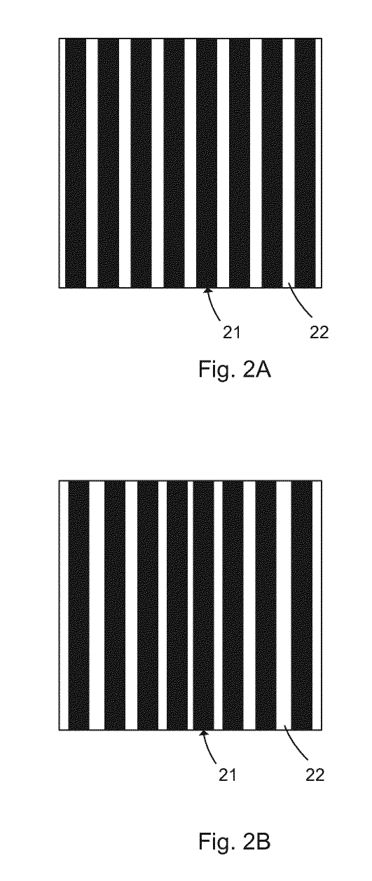

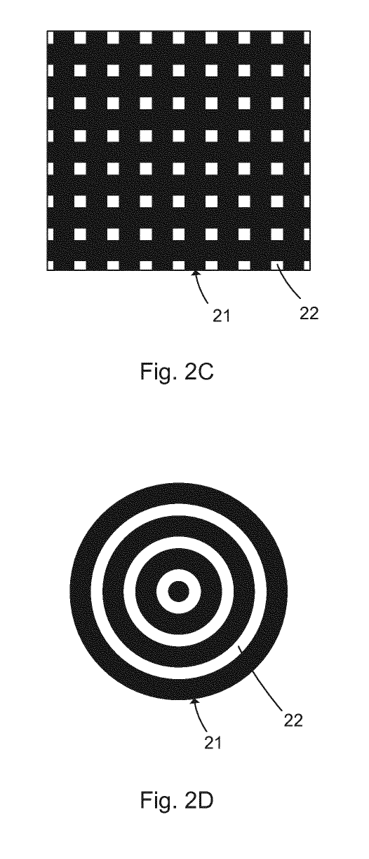

A one-dimensional grating used in a grating layer of a grating reflector could for instance be made of parallel bars of a first material, spaced evenly and being separated by a second material, such as SiO2 or by air or other gaseous substance. The first material could for instance be Si or InP or GaAs or other high-index material. In some embodiments, the grating is non-periodic, such as apodized or chirped or almost-periodic or quasi-periodic or consisting of several sections with different grating periods and/or grating width. Such options are well-known by the person skilled in the art and are applicable as gratings in embodiments of the present invention. The selection of grating depends on the desired properties. FIGS. 2A and 2B are examples of gratings. FIG. 2A shows a periodic grating, and FIG. 2B shows a non-periodic grating.

FIG. 2B shows a two-dimensional grating with square holes. The holes could also be circular or other shape, and the lattice structure could be a triangular or graphite-like-lattice, with circular holes or material; other shapes of the holes can be used. The same high- and low-index materials as discussed in the one-dimensional case are applicable. Such design options for the grating structure are well known by the person skilled in the art. FIG. 2C shows a circular design, which is also a well-known grating pattern. Although the patterns in FIGS. 2A-2C are often used in a surface normal configuration, i.e. with the grating in the plane of the layers, it is also possible to align the grating in the grating layer at an angle with respect to the layer plane. As in the one-dimensional case, the gratings can be for example non-periodic, with changing pitch, duty cycle etc.

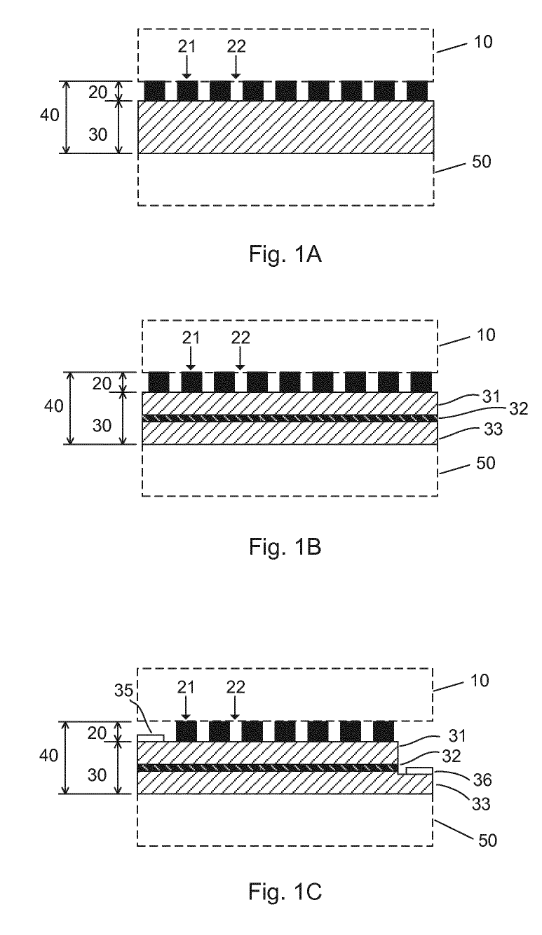

FIGS. 1A, 1B, 1C and 1D illustrate various grating reflectors in accordance with the present invention. The hybrid grating reflector 40 consists of a grating layer 20 and a “cap layer” 30. The grating layer 20 and cap layer 30 are often made of material from two material systems, for instance group III-V and group IV, and in that case the grating reflector may be referred to as a “hybrid grating reflector”. For instance, the grating layer 20 is made of Si and combined with a cap layer 30 made of InP-based materials. In this specification, the term “grating reflector” is generally used.

FIG. 1A illustrates the components of the grating reflector: the cap layer 30, the grating layer 20 and the abutting layers 10 and 50. The high-index sections 21 could for instance be made of Si, which has an index of refraction of about 3.48 (see Table 1) at 1.5-μm (free space) wavelength. The low-index sections 22 can be air (or other gas or mix of gases). Alternatively, depending on the application, materials such as SiNx (Silicon nitride compound), SiO₂, or AlOx (Aluminium oxide compound) can be used, as discussed previously. The same materials can be used around the cap layer, sections 10 and 50. The sections 10 and 50 are indicated with dashed boxes because air is another alternative material, but not being a solid, the extent of these sections depends on the grating reflector's surroundings. Sections 10 and 50 need not be made from the same material. In some cases they are, but using different materials provides much more design flexibility. The cap layer is typically group-III-V based, for instance InP-based, but other choices are available, as discussed above.

It is important to note that the cap layer in accordance with the invention need only to consist of high-index material in a limited region, namely within the core grating region projection defined by the core grating region described previously. FIG. 1D illustrates a structure similar to that in 1C, but with oxide regions 60 for providing current confinement. The dashed box 70 explicitly illustrates that the structure in FIG. 1D has a core grating region even though the cap layer also has low-index regions, namely the oxide regions 60. In other words, the section 70 is the part that makes up a grating reflector in accordance with the present invention. In this example, the grating reflector also has grating sections (that are outside the dashed box) with oxide 60 below them, but the structure as a whole is accordance with the present invention due to the presence of the core grating region 70.

In FIG. 1A the cap layer 30 is made of a single material. The material can be doped or not. If the cap layer 30 is passive, grating reflector 40 operates merely as a reflector.

In many embodiments, however, the cap layer 30 can be active, and typically a composite layer as shown in FIG. 1B, with sublayers such as an active material layer 32 and two cladding layers 31 and 33. The cladding layers can also be composite layers with sublayers. The active material 32 can be a bulk material or contain one or more quantum wells, one or more quantum dot layers, one or more quantum wire layers, one or more quantum dash layers, a buried heterostructure (BH) and so on, or a combination of such materials and material structures. Such an active cap layer can be used for light generation or light absorption or light intensity modulation, depending on the cap layer composition, the wavelength of incident light, use of electrical contacts and so on. Contacts are not shown in FIG. 1A and 1B. These are supplied as needed, if active operation of layer 32 is required. Contacts are illustrated in FIG. 1C. Depending on the bias direction, reverse or forward, the active region can either provide increased absorption or generate photons.

In many embodiments, the high-index sections 21 of the grating layer is group-IV based, typically made of Si. At the same time, the cap layer is typically group-III-V based. In that case, the grating reflector is referred to as a hybrid grating reflector, indicating this hybridised nature.

The refractive indices of both the grating 21 and the cap layer 30 might in some embodiments range from 2.9 to 3.7. As discussed, the refractive indices of surrounding media 10 and 50 and the grating gaps 22 are low, e.g., between 1.0 and 1.8 or 2. The thickness of the grating layer 20 can be, but is not limited to, around 1-1.2 times of the wavelength of interest divided by the refractive index of the grating sections 21. For example, this could be 500 nm for a Si grating when the wavelength of interest is 1550 nm; here, the wavelength of interest can be a central wavelength of the wavelength range where the grating reflector 40 has high reflectivity values. The thickness of the cap layer 30 could range from 0.02 to 2.2 times of the wavelength of interest divided by the refractive index of the cap layer 30, but this is a matter of design and not to be considered a limitation. For example, this can be 10 nm to 1 μm if the cap layer is made of InP and the wavelength of interest is 1550 nm. The refractive indices and thicknesses given above are example values; other values may be used depending on designs, as also discussed

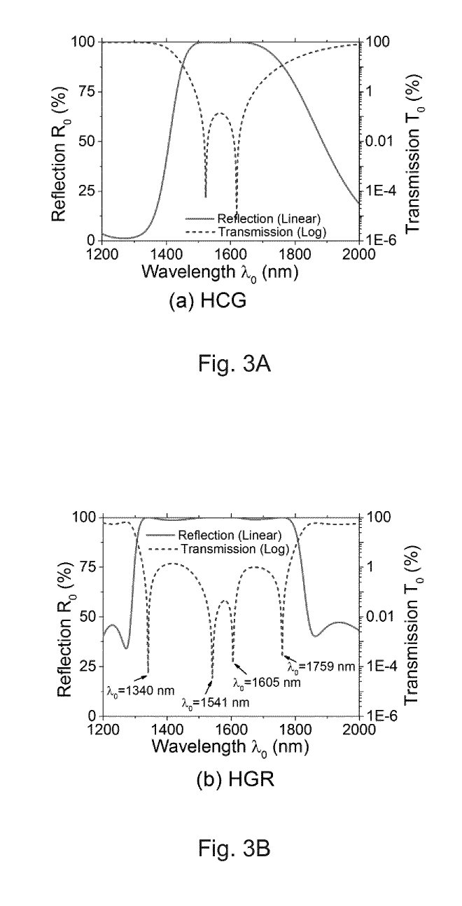

As shown in FIG. 3A, a conventional high-index-contrast grating can provide high reflectivity over broad wavelength range.

The present invention builds in part on the fact that the grating reflector can be designed to have a significantly higher bandwidth than conventional HCGs. In some embodiments of the grating reflector, the normal-incidence reflectivity is at least 99%, such as at least 99.8%. In these embodiments, the grating reflector is novel and inventive, as the prior art has not disclosed the surprisingly effective combination of an HCG and a cap layer that makes it possible to have a high reflectivity across a broad range. In the prior art, a high-index layer is not designed for the obtaining a high reflectivity across a broad range. The presence of the low-index layer on the second side of the cap layer gives the surprising effect. Preferably, a thickness of the cap layer is at most 3 microns. It is even possible to achieve a broad bandwidth around 1550 nm with a cap layer smaller than 1.5 microns. This may advantageously be combined with a grating layer having a thickness of between 200 nm and 700 nm.

FIG. 3B shows the calculated reflection spectrum and transmission spectrum for a grating reflector in accordance with the present invention. The grating layer 20 is made from Si sections 21 and air sections 22, the index of refraction used for the high-index sections 21 is 3.48, the index of refraction used for the low-index sections 22 is 1, the thickness of the grating layer is 497 nm, the grating period is 735 nm, the duty cycle is 0.45 (i.e. the Si (high-index) section 21 is 331 nm wide and the air (low index) section 31 is 404 nm wide), the cap layer 30 is InP and has a thickness of 310 nm and a refractive index of 3.166. The calculations are based on TM polarized light incident from air in a surface-normal direction from the cap layer side of the grating reflector.

Comparing the spectra of FIG. 3A and 3B it is clear that the present invention can provide a high reflectivity over a broader wavelength range compared to the high-index-contrast gratings (HCG's) of the prior art, including conventional HCGs as well as 0-gap HCG's

It is a key aspect that the grating reflector includes the “cap layer” described above. The hybrid reflector is defined by four geometrical parameters, i.e., grating period, grating thickness, grating duty cycle, and cap layer thickness. In the previously discussed WO2013/110004 A1, there are only three parameters available. The high-index layer in WO 2013/110004A1 situated at a location similar to the cap layer in the grating reflector does not play the same role. An important reason for this is that the incident medium in the present invention is a low refractive index material 50. In the prior art, the cavity 60 is made of high-index material, while in the present invention, the cavity is made of low-index material, which leads to fundamentally different optical modes.

VCSEL with a Hybrid Grating Reflector Operating as an Integrated Modulator

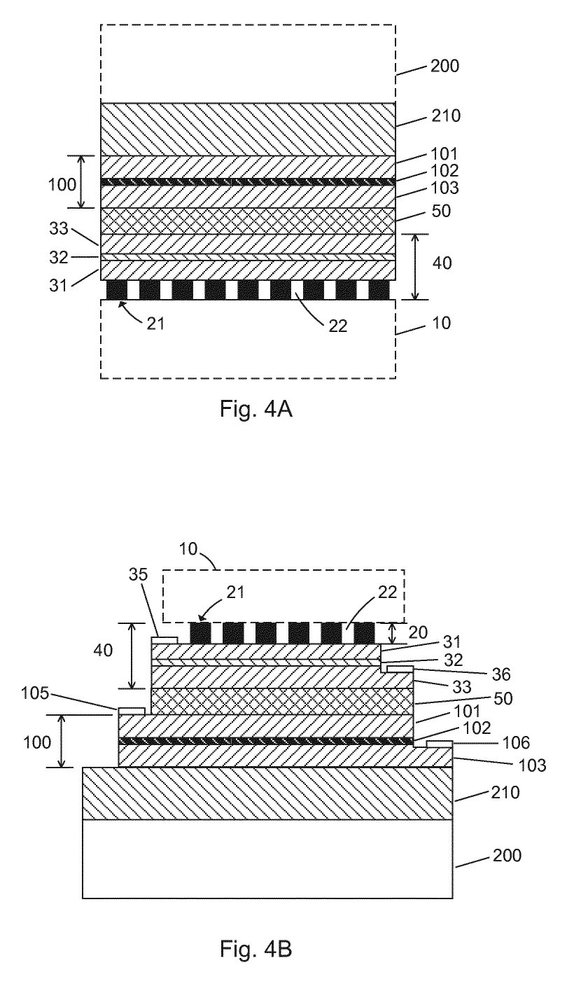

FIG. 4A shows a layer structure for a VCSEL in accordance with an aspect of the present invention. It has a hybrid grating reflector 40 and another reflector 210. These two reflectors form an optical cavity. There are two active regions. The first active region 32 is a part of the hybrid grating reflector 40 and has cladding layers 31 and 33. The second active region 102 is a part of the optical cavity and has cladding layers 101 and 103. The optical cavity also contains a low-index layer 50 abutting the cap layer of the hybrid grating reflector. The grating layer 20 has high-index sections 21 made, in this example, of Si (since it is a hybrid grating reflector in the present example). The low-index sections 22 of the grating are, in this example, made of air.

The active region 102 can be made with materials and a configuration as described above in relation to layer 32 of the grating reflector, that is: it can be bulk material or contain one or more quantum wells, one or more quantum dot layers, one or more quantum wire layers, one or more quantum dash layers, a buried heterostructure (BH) and so on, or a combination of such materials and material structures. The layer 101 and/or 103 may include an optical confinement structure and/or an electrical confinement structure. This is a matter of design and affects device efficiency and optical and electrical properties. The illustrated design is simple and efficient.

FIG. 4B illustrates a VCSEL using the VCSEL structure shown in FIG. 4A. The grating reflector is operable as an integrated intensity modulator.

Electric current is supplied to the active material 102 through cladding layers 101 and 103 for light generation. Metal contacts 105 and 106 are used for supplying electric current. Structures for lateral confinement of electronic current such as an oxide aperture and a tunnel junction can be included in either cladding layers 101 or 103, or in both of them. The low-index layer 50 is SiO₂, or AlO or BCB, for example.

The reflector 210 can for instance a distributed Bragg reflector, a conventional high-index-contrast grating, or another grating reflector or hybrid grating reflector, or other type of suitable mirror.

By supplying reverse bias or forward bias to the active material 32, the refractive index and absorption coefficient of the active material 32 can be changed. Metal contacts 35 and 36, or metal contacts 35 and 105 are used for this supply. In FIG. 4B, the metal contacts 35 and 36 are dedicated to the supply to the active material 32 for intensity modulation while the metal contacts 105 and 106 are dedicated to the supply of current to the active material 102 for light generation.

VCSEL with Light Generation from a Hybrid Grating Reflector

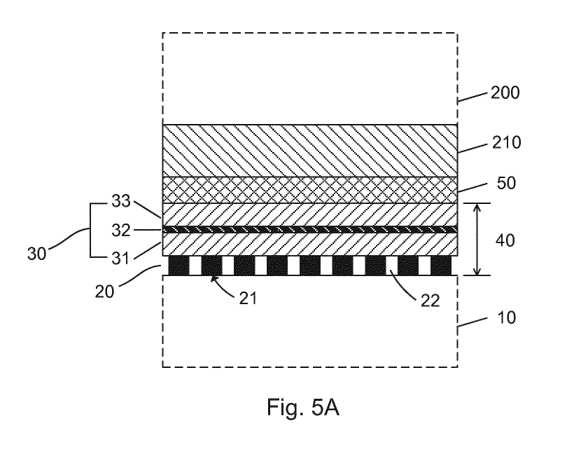

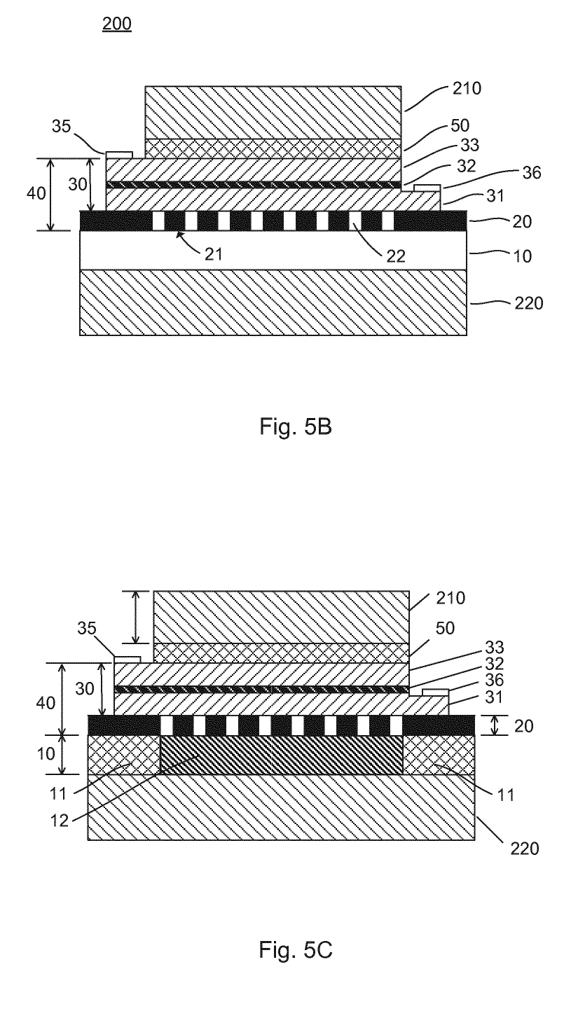

FIG. 5A shows another embodiment of a VCSEL structure in accordance with an aspect of the invention, and FIG. 5B and 5C are embodiments that include suitable metal contacts.

FIG. 5A shows a layer structure for a VCSEL in accordance with an aspect of the present invention. It has a hybrid grating reflector 40 and another reflector 210. As opposed to the VCSEL structure shown in FIG. 4A, the optical cavity 50 formed by two reflectors 40 and 210 does not include an active region (102 in FIG. 4A). The first and only active region 32 is included as a part of the hybrid grating reflector 40. This in itself is quite different from conventional VCSEL structures where an active region is located in such a way that it utilizes the strong light intensity in the optical cavity to enhance stimulated emission. In the present VCSEL structure, the active material 32 included in the hybrid grating reflector 40 generates the photons for lasing. The grating reflector therefore acts as both reflector and photon generator.

In FIG. 5A the cap layer 30 of the hybrid grating reflector 40 consists of the active material 32 and cladding layers 31 and 33. Electric current can be supplied to the active material 32 through the cladding layers 31 and 33 for light generation. Structures for lateral confinement of electronic current such as an oxide aperture and a tunnel junction can be included outside the projection of the core grating region. Within the core grating region and projection thereof onto the cap layer of the grating reflector part, the indices of refraction of the cap layer must, in accordance with the invention, be high.

In FIGS. 5B and 5C, the metal contacts 35 and 36 are used to supply current to the active material 32 for light generation.

For lateral confinement of current, a structure such as an oxide aperture or a tunnel junction can be included for instance in the cladding 31 or 33. Alternatively, the active material 32 can be included within a buried heterostructure.

When light is incident on the hybrid grating reflector 40, it excites several modes in the grating layer 20 and the cap layer 30. These excited modes collectively form a standing wave intensity pattern within the hybrid grating reflector. The light intensity at one of the anti-node positions of the standing wave pattern within the cap layer 30 is comparable to or even higher than that at one of the anti-node positions within the optical cavity. Thus, equivalently efficient stimulated emission as in conventional VCSEL structures can be obtained. This is fundamentally different from the principles of the prior art.

An apparent structural difference from the conventional VCSEL structures is that the active material for light generation is located not in the optical cavity per se but in a reflector. As a result, the volume, V, of the optical mode formed by the optical cavity is considerably smaller in the VCSEL structure shown in FIG. 5A than in conventional VCSEL structures. This results in part because low-index layer 50 in the optical cavity can be quite thin, for instance between 250 and 600 nm. This leads to considerable increase in the intrinsic modulation speed of the VCSEL that is to some degree proportional to V^{-1/2}.

Another consequence is that an equivalent series resistance, R, and capacitance, C, are considerably smaller, easing the RC time constant limit, the extrinsic modulation speed to some extent scaling as (RC)^{-1/2}.

The structure in FIG. 5B does not need sacrificial etching to form the lower refractive index layer 10. The layer 10 should be made of a lower refractive index material.

After forming the grating pattern in the grating layer 20, the cap layer 30 is wafer-bonded onto the grating layer 20.

The low-index layer 50 can be made of SiNx, SiO₂, or AlOx. SiNx and SiO2 should be deposited, AlOx can be epitaxially grown and oxidized, and air can be formed by sacrificial etching.

The reflector 210 can be a deposited dielectric DBR, an epitaxially grown DBR, a high-index-contrast grating, or another grating reflector or hybrid grating reflector.

Fabrication of the embodiment in FIG. 5C requires sacrificial etching to form the lower refractive index part 10. Originally, the region to be the lower refractive index part 10 can be made of a high refractive index material and then that region is removed by sacrificial etching. After forming the grating pattern in the grating layer 20, the low-index part 10 is formed by sacrificial etching. Then, the cap layer 30 is wafer-bonded onto the grating 20. The result is an air section 12 and elements 11 which are semiconductor material.

RCEPD with Light Absorption in a Hybrid Grating Reflector

The structures in FIGS. 5A to 5C can be used for light detection. A reverse bias is applied between two cladding layers to facilitate the extraction of electrons generated in the active material 32 as a result of light absorption.

The amount of light absorption can be enhanced if a light-absorbing material is positioned at one of light intensity anti-nodes of the standing wave pattern in the optical cavity. In the structures in FIGS. 5A to 5C, an antinode in the cap layer 30 can be used. A very high light absorption efficiency value close to 100% can be obtained. The light absorption efficiency counts for the fraction of absorbed light over incident, coupled light.

Lateral Emission into an In-Plane Waveguide

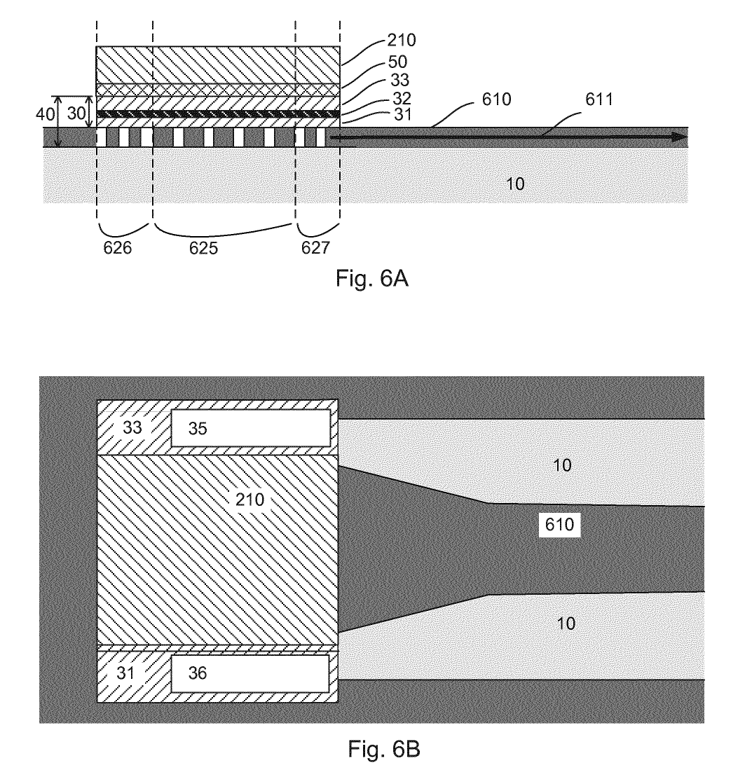

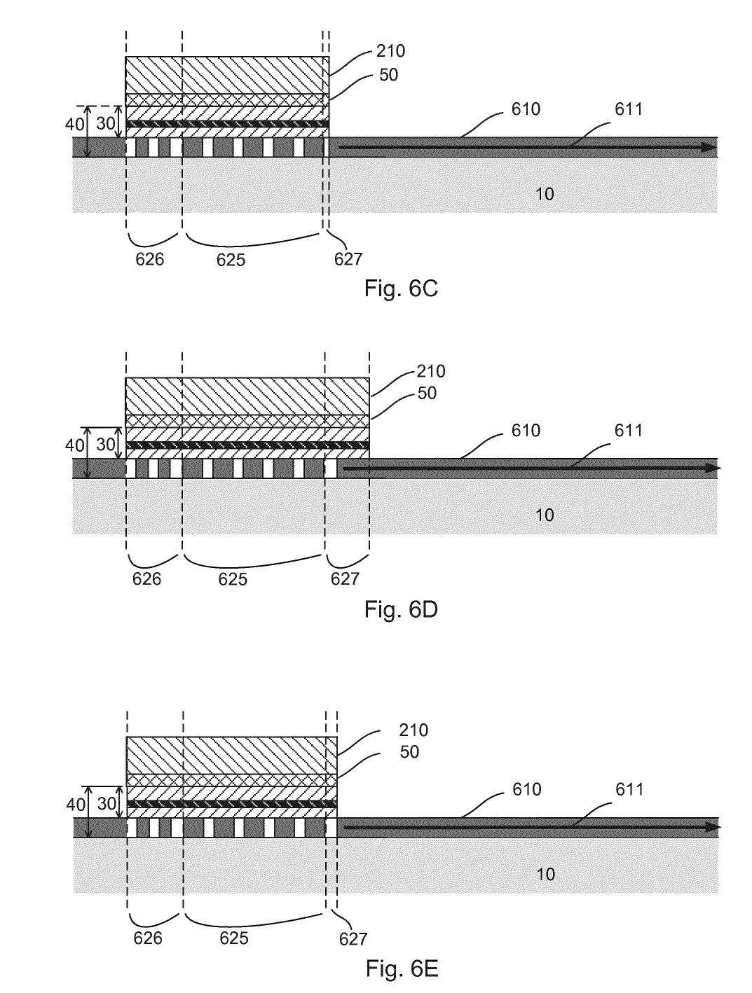

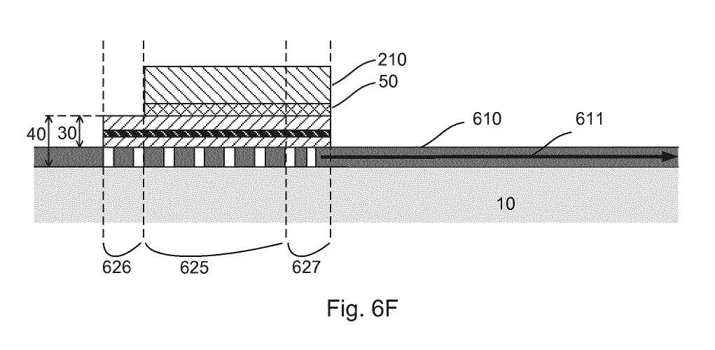

FIGS. 6A-6F illustrate VCSEL structure embodiments comprising an output waveguide for coupling optical power 611 out in a lateral direction. To avoid vertical emission, the first reflector 210 and the grating reflector 40 have high reflectivities, preferably at least 99%. Reflectivities of at least 99.8% are advantageous in some cases. This increases coupling out in the lateral direction.

FIG. 6A illustrates an embodiment having three separate sections. Section 625 is a core section in which the grating in the grating layer has a certain constitution, including number of high-index and low-index sections, having certain pitches and duty cycle(s). The grating layer is also characterized by its thickness. A confinement section 626 provides in-plane confinement at or very near a lasing wavelength to prevent coupling of optical power through section 626. Section 627 is a coupling section that improves a coupling efficiency out of the core section 625 and into the external waveguide. In FIG. 6A, the grating parameters in section 627 differ from those in the core section 625, and the inventors have found that this can significantly improve coupling efficiency of optical power into the external waveguide.

FIG. 6B illustrates an embodiment similar to FIG. 6A, seen in a top view. Two contacts 35 and 36 are incorporated to allow optical amplification in the active region 32. In the embodiment in FIG. 6B, the two contacts are separated by at least a width of the external waveguide at the beginning of the external waveguide. This helps suppress carrier crowding that may happen in this intra-cavity contact scheme (in which one metal contact is formed below a upper mirror and another metal contact is formed above a lower mirror, the two mirrors forming an optical cavity; this scheme is not shown in FIG. 6A).

FIG. 6C illustrates an embodiment in which the coupling section is a narrow low-index section. Preferably, the width of this section is between 35 and 65% of the width of low-index sections in the core section. If the widths differ among each other within the core section, the width of the narrow low-index section is between 35 and 65% of the width of the nearest low-index section in the core section.

FIG. 6D illustrates an embodiment in which the external waveguide abuts a high-index section having a width that exceeds a maximum width of high-index sections in the core section. This may also improve the coupling efficiency.

FIG. 6E is similar to FIG. 6C. However, the low-index section abutting the external waveguide has a width equal to, or at least substantially equal to, a width of the nearest low-index section in the core section.

FIG. 6F illustrates an embodiment in which the confinement section does not have layer 50 and 210 above it. This provides transverse confinement.

In some embodiments, the confinement section 626 may have different grating parameters from the core section 625, leading to a different resonance wavelength in the confinement section 626. This provides transverse confinement.

In some embodiments, the grating parameters of the grating layer of the confinement section 626 can be chosen to form a Bragg reflector. This provides transverse confinement.

In some embodiments, the cap layer of the confinement section 626 has a Bragg reflector pattern. This provides transverse confinement.

The external waveguide could alternatively extend in another direction relative to the grating structure in the grating layer, such as parallel to the bars in case of a grating such as that in FIG. 2A or 2B. Any angle is possible. The structures illustrated in FIGS. 6A to 6F take full advantage of the differences between the grating parameters in the confinement section 626, the core section 625 and the coupling section 627.

1. A VCSEL structure comprising:
a first reflector,
a grating reflector, the grating reflector forming an optical cavity with the first reflector,
wherein the grating reflector comprises:
a grating layer having a first side and having a second side opposite the first side and comprising a contiguous core grating region having a grating structure, wherein an index of refraction of high-index sections of the grating structure is at least 2.5, and wherein an index of refraction of low-index sections of the grating structure is less than 2, the core grating region defining a projection in a direction normal to the grating layer,
a cap layer having a first side and having a second side opposite the first side, the first side of the cap layer abutting the second side of the grating layer, and the cap layer within the projection of the core grating region onto the cap layer consists of material having an index of refraction of at least 2.5; and within the projection of the core grating region, the second side of the cap layer is abutted by a first solid dielectric low-index layer, an index of refraction of the first low-index being less than 2; and within the projection of the core grating region, the first side of the grating layer is abutted by a second dielectric low-index layer and/or by air, an index of refraction of the second low-index layer or air being less than 2,
the VCSEL structure further comprising a first active region located in the cap layer of the grating reflector for generating or absorbing photons.

2-25. (canceled)

26. The VCSEL structure in accordance with claim 1, wherein the first low-index layer comprises SiNx, SiO₂, or AlOx, and the second low-index layer comprises SiNx, SiO₂, or AlOx.

27. The VCSEL structure in accordance with claim 1, wherein the first low-index layer comprises SiNx, SiO₂, AlOx, or BCB, and the second low-index layer comprises SiNx, SiO₂, or AlOx.

28. The VCSEL structure in accordance with claim 1, wherein the core grating region comprises at least 3 high-index sections.

29. The VCSEL structure in accordance with claim 1, wherein a thickness of the cap layer is between 300 nm and 1.5 microns.

30. The VCSEL structure in accordance with claim 1, wherein one or more of the high-index regions of the grating region is made of Si or is InP-based or GaAs-based.

31. The VCSEL structure in accordance with claim 1, further comprising at least two first active region contacts positioned to allow a voltage to be applied across the first active region for either generating photons or changing an absorption of the first active region.

32. The VCSEL structure in accordance with claim 31, wherein the first active region generates photons for supporting a lasing state in a VCSEL comprising the VCSEL structure of claim 31 when a sufficient forward-bias voltage is applied across the first active region.

33. The VCSEL structure in accordance with claim 1, wherein the VCSEL structure further comprises a second active region configured such that the first low-index layer is situated between the first active region and the second active region, and the second active region is configured to modulate an optical output from the optical cavity when a sufficient and time-varying reverse or forward bias voltage is applied across it.

34. The VCSEL structure in accordance with claim 31, further comprising at least two second active region contacts, which allow application of a forward-bias voltage or reverse-bias voltage across the second active region.

35. The VCSEL structure in accordance with claim 1, wherein the first reflector is a distributed Bragg reflector or a high-contrast grating or a grating reflector or other reflector compatible with the VCSEL structure.

36. The VCSEL structure in accordance with claim 1, further comprising an output waveguide in the grating layer, the output waveguide comprising an external waveguide beginning from and extending beyond a projection of a first edge of the optical cavity onto the grating layer.

37. The VCSEL structure in accordance with claim 36, wherein the external waveguide is at least 10 microns long.

38. The VCSEL structure in accordance with claim 36, comprising a core section in which a normal-incidence reflectivity of the combined cap layer and grating layer is at least 99%.

39. The VCSEL structure in accordance with claim 38, wherein the core section extends to the beginning of the external waveguide.

40. The VCSEL structure in accordance with claim 36, comprising:
a core section with grating parameters resulting in which a normal-incidence reflectivity of the combined cap layer and grating layer is at least 99%, and
a coupling section between the core section and the external waveguide, the coupling section having grating parameters different from grating parameters of the core section.

41. The VCSEL structure in accordance with claim 40, wherein the grating layer in the coupling section comprises a narrow low-index section having a width in the interval 35 to 65% of a smallest width of low-index sections within the core section, and the narrow low-index section abuts the external waveguide.

42. The VCSEL structure in accordance with claim 40, wherein the external waveguide is integral with a wide high-index section in the coupling section, the wide high-index region having a width exceeding a highest width of high-index sections within the core section,
and, wherein the external waveguide tapers from a first width at the beginning of the external waveguide, to a narrower width.

43. The VCSEL structure in accordance with claim 36, further comprising a confinement section having grating parameters different from grating parameters of the core section.

44. The VCSEL structure in accordance with claim 36, further comprising:
at least two first active region contacts positioned to allow a voltage to be applied across the first active region for either generating photons or changing an absorption of the first active region, wherein the first active region contacts are located in a north position and a south position relative to the core section and the external waveguide is located in an east position relative to the core section, when seen in a direction normal to the first reflector.
